(19) United States
(12) Patent Application Publication
(10) Pub. No.: US 2022/0230878 A1
(43) Pub. Date: Jul. 21, 2022

(54) SEMICONDUCTOR COMPOSITE LAYERS

(71) Applicant: Hewlett-Packard Development Company, L.P., Spring, TX (US)

(72) Inventors: Hsing-Hung Hsieh, Taipei City (TW); Kuan-Ting Wu, Taipei City (TW); Super Liao, Taipei City (TW)

(73) Assignee: Hewlett-Packard Development Company, L.P., Spring, TX (US)

(21) Appl. No.: 17/614,590

(22) PCT Filed: Sep. 5, 2019
(86) PCT No.: PCT/US2019/049667

§ 371 Date: Nov. 29, 2021

(51) Int. Cl. H01L 21/02; H01L 27/12; H01L 29/786

(52) U.S. Cl. CPC H01L 21/02535; H01L 29/7869; H01L 27/1225; H01L 21/02667

(57) ABSTRACT

A semiconductor composite layer can include a source electrode and a drain electrode individually comprising both a carrier mobility contributor and an amorphous phase stabilizer. The semiconductor composite layer can further include a semiconductive portion disposed between the source electrode and the drain electrode wherein the semiconductive portion comprises the carrier mobility contributor and the amorphous phase stabilizer, the semiconductivity controller comprising oxygen and an element having an electrode potential that is lower than that of both the carrier mobility contributor and the amorphous phase stabilizer.

### BACKGROUND

Semiconductor materials have an electrical conductivity value falling between a conductor and an insulator. Many semiconductor materials are crystalline solids, such as crystalline silicon. In some examples, faults in the crystal structure can interfere with the semiconducting properties of the material. Nonetheless, semiconductor devices can have a variety of useful properties, such as passing current more easily in one direction than the other, variable resistance, sensitivity to light, sensitivity to temperature, etc. Further, much of the current electronics technology employs semiconductor materials, such as utilized in many transistors, integrated circuits, etc.

### BRIEF DESCRIPTION OF THE DRAWINGS

FIG. 1 is a schematic representation of an example semiconductor material in accordance with the present disclosure;

FIG. 2 is a schematic representation of an example semiconductor device in accordance with the present disclosure;

FIG. 3 is a schematic representation of an example electronic device in accordance with the present disclosure;

FIG. 4 is a flowchart illustrating an example method of manufacturing a semiconductor composite layer in accordance with examples of the present disclosure; and

FIGS. 5A-5F are cross-sectional views showing an example method of manufacturing a semiconductor composite layer in accordance with the present disclosure.

### DETAILED DESCRIPTION

Many semiconductor materials, such as silicon, benefit from a high degree of crystallinity, as dislocations and other faults can interfere with the semiconducting properties of the material. However, some semiconductor materials, such as oxide-based semiconductors, can be amorphous. Compared to many semiconductors, oxide-based semiconductors can often have high performance, a broad range of properties and applications, and low cost. In some cases, oxide-based semiconductor materials can suffer from uniformity and stability issues. The present disclosure describes oxide-based semiconductor materials and associated devices having high performance and a high degree of customization while maintaining good uniformity and stability.

In one example, a semiconductor material can include a carrier mobility contributor, an amorphous phase stabilizer, and a semiconductivity controller. The semiconductivity controller may be fused to the carrier mobility contributor and the amorphous phase stabilizer through annealing or another heating process. A layer can include the carrier mobility contributor and the amorphous phase stabilizer. The semiconductivity controller may be placed over such a layer and then fused into a portion of the layer. Portions of the layer that are not fused with the semiconductivity controller may serve as source and drain electrodes in a semiconductor device. The carrier mobility contributor can be selected from a period 6 metal or a period 5 metal. For example, the period 6 metal can be lead and the period 5 metal can be indium, tin, cadmium, or a combination thereof. In one example, the carrier mobility contributor is not a combination of the period 6 metal and the period 5 metal. In one example, the amorphous phase stabilizer can be selected from indium, tin, cadmium, zinc, gallium, or a combination thereof when the carrier mobility contributor is the period 6 metal. Alternatively, the amorphous phase stabilizer can be selected from zinc, gallium, or a combination thereof when the carrier mobility contributor is the period 5 metal. In a further example, the semiconductivity controller can be composed of oxygen and an element having an electrode potential that is lower than that of both the carrier mobility contributor and the amorphous phase stabilizer. For example, the semiconductivity controller can have an electrode potential from −0.8 to −3.1. In various examples, the semiconductivity controller can be composed of Al₂O₃, SiO₂, HfO₂, or Ta₂O₃. In still another specific example, a semiconductor material can include from about 11 atomic percent (at %) to about 50 at % of a carrier mobility contributor selected from a period 6 metal or a period 5 metal, wherein the period 6 metal is lead and the period 5 metal is indium, tin, cadmium, or a combination thereof, and wherein the carrier mobility contributor is not a combination of the period 6 metal and the period 5 metal; from about 0.6 at % to about 25 at % of an amorphous phase stabilizer, wherein the amorphous phase stabilizer is selected from indium, tin, cadmium, zinc, gallium, or a combination thereof when the carrier mobility contributor is the period 6 metal, or the amorphous phase stabilizer is selected from zinc, gallium, or a combination thereof when the carrier mobility contributor is the period 5 metal; from about 0.3 at % to about 18 at % of a semiconductivity controller including an element having a standard electrode potential from about −0.8 to about −3.1, with from about 45 at % to about 67 at % oxygen. In some examples, the carrier mobility contributor and the amorphous phase stabilizer are present at an atomic ratio of from about 1:2 to about 50:1. In some additional examples, the carrier mobility contributor and the semiconductivity controller are present at an atomic ratio of from about 2:3 to about 150:1. In some further examples, the amorphous phase stabilizer and the semiconductivity controller are present at an atomic ratio of from about 1:30 to about 80:1. In some examples, the carrier mobility contributor is lead, and the amorphous phase stability is selected from indium, tin, cadmium, zinc, gallium, or a combination thereof. In other examples, the carrier mobility contributor is indium, tin, cadmium, or a combination thereof, and the amorphous phase stabilizer is zinc, gallium, or a combination thereof. In additional examples, the semiconductivity controller includes an alkali metal, an alkaline earth metal, a lanthanide, an actinide, or a combination thereof. In other examples, the semiconductivity controller includes a transition metal.

In another example, a method of manufacturing a semiconductor composite layer can include, for example, depositing an intermediate layer over a semiconductive support layer wherein the intermediate layer includes a carrier mobility contributor and an amorphous phase stabilizer. The carrier mobility contributor can be selected from a period 6 metal or a period 5 metal. For example, the period 6 metal can be lead and the period 5 metal can be indium, tin, cadmium, or a combination thereof. The carrier mobility contributor may not be a combination of the period 6 metal and the period 5 metal. The amorphous phase stabilizer can be selected from indium, tin, cadmium, zinc, gallium, or a combination thereof when the carrier mobility contributor is the period 6 metal. Alternatively, the amorphous phase stabilizer can be selected from zinc, gallium, or a combination thereof when the carrier mobility contributor is the period 5 metal. The method can further include depositing a semiconductivity controller over a portion of the intermediate layer. The semiconductivity controller can comprise oxygen and an element having an electrode potential that is lower than that of both the carrier mobility contributor and the amorphous phase stabilizer. In this example, the method further includes fusing the semiconductivity controller to the portion of the intermediate layer such that the semiconductivity controller penetrates the intermediate layer and combines with the carrier mobility contributor and the amorphous phase stabilizer at the portion to form an oxide-containing semiconductor material positioned between two portions of the intermediate layer where the semiconductivity controller was not deposited and fused into the intermediate layer. In one specific example, the two portions of the intermediate layer form a source electrode and a drain electrode, both of which include the carrier mobility contributor and the amorphous phase stabilizer, but not the semiconductivity controller. In still another example, the semiconductive support layer can be formed by depositing a gate electrode over a portion of a substrate and depositing a gate insulator material over exposed surfaces of the gate electrode and over the substrate, wherein the intermediate layer is deposited over a surface of the gate insulator material. The semiconductivity controller can include Al₂O₃, SiO₂, HfO₂, or Ta₂O₃, for example. The fusing of the semiconductivity controller to the portion of the intermediate layer may be accomplished via an annealing process, for example. Furthermore, in another example, the fusing of the semiconductivity controller to the portion of the intermediate layer may be accomplished by heating the semiconductivity controller and the intermediate layer to a temperature from about 200° C. and about 500° C.

In other examples, an electronic device can include a semiconductor composite layer that can include a semiconductive portion disposed between a drain electrode and a source electrode, a gate electrode, and a dielectric material or gate insulator positioned between the gate electrode and the semiconductive portion and the drain and source electrode. The semiconductive portion can be composed of a carrier mobility contributor, an amorphous phase stabilizer, a semiconductivity controller, and oxygen. The carrier mobility contributor can be selected from a period 6 metal or a period 5 metal. For example, the period 6 metal can be lead and the period 5 metal can be indium, tin, cadmium, or a combination thereof. In one example, the carrier mobility contributor is not a combination of the period 6 metal and the period 5 metal. In one example, the amorphous phase stabilizer can be selected from indium, tin, cadmium, zinc, gallium, or a combination thereof when the carrier mobility contributor is the period 6 metal. Alternatively, the amorphous phase stabilizer can be selected from zinc, gallium, or a combination thereof when the carrier mobility contributor is the period 5 metal. In one example, the semiconductivity controller can be composed of oxygen and an element having an electrode potential that is lower than that of both the carrier mobility contributor and the amorphous phase stabilizer. The electronic device can include, for example, a display, an amplifier, a memory device, a global positioning system (GPS) device, a server, a modem, a router, a personal computer, a laptop computer, a calculator, a tablet, a phone, a speaker, a television, a media player, a projector, a smart device, a remote control, or a combination thereof.

In addition to the examples described above, including the semiconductor composite layer, the methods of manufacture, and the electronic devices will be described in greater detail below. It is also noted that when discussing the semiconductor composite layers, methods, and electronic devices described herein, these relative discussions can be considered applicable to the other examples, whether or not they are explicitly discussed in the context of that example. Thus, for example, in discussing a carrier mobility contributor related to a semiconductor composite layer, such disclosure is also relevant to and directly supported in the context of the methods and electronic devices described herein, and vice versa.

### Semiconductor Composite Layers

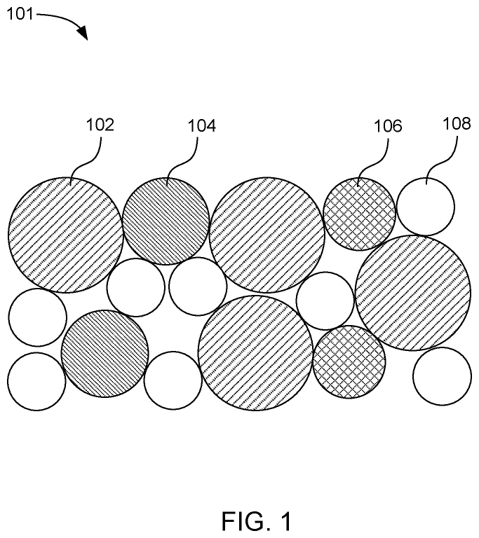

In further detail, the semiconductor composite layers and electronic devices described herein can be prepared using various semiconductor materials. For example, FIG. 1 provides an example semiconductor material 101 that can be used to form a semiconductor layer and/or a device that includes a semiconductor layer as described herein. The semiconductor material can include a carrier mobility contributor 102, an amorphous phase stabilizer 104, a semiconductivity controller 106, and oxygen 108. It is noted that the different components are not drawn to scale, may not be drawn in an expected relationship, or the like. FIG. 1 is provided for illustrative purposes for understanding aspects of an example herein.

As mentioned, one of the materials selected for use can include a carrier mobility contributor 102. The carrier mobility contributor can have good carrier (e.g. electron or hole) transport properties. Generally, the carrier mobility contributor can include a metal that, when oxidized, has an electronic configuration of (n−1)d¹⁰ns⁰. This generally refers to the metals in groups 11 through 15 and periods (n) 4 through 6 of the periodic table, e.g., copper, zinc, gallium, germanium, arsenic, silver, cadmium, indium, tin, antimony, gold, mercury, thallium, lead, bismuth, etc. However, in some examples, the carrier mobility contributor can also benefit from readily forming a metal oxide. As such, in some examples, the carrier mobility contributor also has a negative standard electrode potential (SEP). In further detail, of those metals previously listed, including lead, cadmium, indium, tin, zinc, and gallium, have a negative SEP. Thus, in some examples, the carrier mobility contributor can include lead, cadmium, indium, tin, zinc, or gallium. In some specific examples, the carrier mobility contributor can include lead, cadmium, indium, or tin. In some further examples, the carrier mobility contributor can be or includes lead. In some other examples, the carrier mobility contributor can be or includes cadmium, indium, tin, or a combination thereof.

The carrier mobility contributor 102 can be present in the semiconductor material 101 in a variety of amounts. Generally, the carrier mobility contributor can be present in the semiconductor material in an amount from about 11 at % to about 50 at % based on the total number of atoms in the semiconductor material. In some additional examples, the carrier mobility contributor can be present in the semiconductor material in an amount from about 15 at % to about 25 at %, from about 20 at % to about 30 at %, from about 25 at % to about 35 at %, from about 30 at % to about 40 at %, from about 35 at % to about 45 at %, or from about 40 at % to about 50 at % based on the total number of atoms in the semiconductor material.

The semiconductor materials 101 can also include an amorphous phase stabilizer 104. Similar to the carrier mobility contributor, the amorphous phase stabilizer can also have good carrier transport properties and can include a metal that, when oxidized, has an electronic configuration of (n−1)d¹⁰ ns⁰. Additionally, the amorphous phase stabilizer can also generally include a metal having a negative SEP (e.g. lead, cadmium, indium, tin, zinc, or gallium). The amorphous phase stabilizer can be present to help prevent the semiconductor material from crystallizing. As such, the amorphous phase stabilizer can generally be from a different period of the periodic table than the carrier mobility contributor to disrupt the crystalline structure of the carrier mobility contributor. In some specific examples, the amorphous phase stabilizer can be from a lower numbered period of the periodic table than the carrier mobility contributor. In some further examples, the amorphous phase stabilizer can be or includes cadmium, indium, tin, zinc, gallium, or a combination thereof. In some examples, the amorphous phase stabilizer can include one of cadmium, indium, tin, zinc, or gallium. In some additional examples, the amorphous phase stabilizer can include two of cadmium, indium, tin, zinc, or gallium. In some additional specific examples, the amorphous phase stabilizer can be or includes cadmium, indium, tin, or a combination thereof. In some examples, the amorphous phase stabilizer can include one of cadmium, indium, or tin. In some additional examples, the amorphous phase stabilizer can include two of cadmium, indium, or tin. In some other examples, the amorphous phase stabilizer can be or includes zinc, gallium, or a combination thereof. In some examples, the amorphous phase stabilizer can include one of zinc, or gallium. In some additional examples, the amorphous phase stabilizer can include zinc and gallium.

The amorphous phase stabilizer 104 can be present in the semiconductor material 101 in a variety of amounts. Generally, the amorphous phase stabilizer can be present in the semiconductor material in an amount from about 0.6 at % to about 25 at % based on the total number of atoms in the semiconductor material. In some additional examples, the amorphous phase stabilizer can be present in the semiconductor material in an amount from about 1 at % to about 10 at %, from about 5 at % to about 15 at %, from about 10 at % to about 20 at %, or from about 15 at % to about 25 at % based on the total number of atoms in the semiconductor material.

The semiconductor materials 101 can also include a semiconductivity controller 106 as a component of the material. The semiconductivity controller can help enhance the stability of the semiconductor materials and can help tune the semiconductive properties of the semiconductor materials. For example, the carrier mobility contributor and the amorphous phase stabilizer components are generally conductive materials unless oxidized. As such, the level of oxygen in the material can determine whether the material behaves more like a conductive material or semiconductor material. For example, where the level of oxygen in the semiconductor material is low, the semiconductor material may behave more similarly to a conductive material than a semiconductor material. Thus, the semiconductivity controller can help achieve and maintain a level of oxygen that promotes semiconductive properties in the semiconductor material. Accordingly, the semiconductivity controller can generally have a low standard electrode potential to help tune the amount of oxygen in the semiconductor material, for example. More specifically, the semiconductivity controller can generally have a standard electrode potential (SEP) that is less than −0.8, e.g., from about −0.8 to about −3.1. In some specific examples, the semiconductivity controller can have an SEP of from about −0.8 to about −3.05, from about −1.0 to about −2.0, from about −1.5 to about −2.5, or from about −2.0 to about −3.0. The semiconductivity controller can also be used to tune a variety of other properties of the semiconductor material for various applications as well.

The semiconductivity controller 106 can be composed of Al₂O₃, SiO₂, HfO₂, or Ta₂O₃. In some specific examples, the semiconductivity controller can include an alkali metal, an alkaline earth metal, a lanthanide, an actinide, a transition metal, a metalloid, a post-transition metal, or a combination thereof. In some examples, the semiconductivity controller can include an alkali metal, an alkaline earth metal, a lanthanide, an actinide, a transition metal, a post-transition metal, or a combination thereof. In some other examples, the semiconductivity controller can include an alkali metal, an alkaline earth metal, a lanthanide, an actinide, a transition metal, a metalloid, or a combination thereof. In some additional examples, the semiconductivity controller can include an alkali metal, an alkaline earth metal, a lanthanide, an actinide, a transition metal, or a combination thereof. In some examples, the semiconductivity controller can include an alkali metal, an alkaline earth metal, a lanthanide, an actinide, or a combination thereof.

In some examples, the semiconductivity controller 106 can include an alkali metal. Suitable alkali metal metals can include lithium (SEP −3.04), sodium (SEP −2.71), potassium (SEP −2.93), rubidium (SEP −2.92), cesium (SEP −2.92), francium (SEP −2.92), or a combination thereof. In some additional examples, the semiconductivity controller can include an alkaline earth metal. Suitable alkaline earth metals can include beryllium (SEP −1.97), magnesium (SEP −2.66), calcium (SEP −2.84), strontium (SEP −2.89), barium (SEP −2.92), radium (SEP −2.92), or a combination thereof. In still additional examples, the semiconductivity controller 106 can include a lanthanide. Suitable lanthanides can include lanthanum (SEP −2.38), cerium (SEP −2.34), praseodymium (SEP −2.35), neodymium (SEP −2.2), promethium (SEP −2.29), samarium (SEP −2.67), europium (SEP −2.8), gadolinium (SEP −2.28), terbium (SEP −2.31), dysprosium (SEP −2.2), holmium (SEP −2.33), erbium (SEP −2.32), thulium (SEP −2.3), ytterbium (SEP −2.8), lutetium (SEP −2.3), or a combination thereof. In some further examples, the semiconductivity controller can include an actinide. Suitable actinides can include plutonium (SEP −1.2), americium (SEP −1.95), curium (SEP −1.2), berkelium (SEP −1.6), californium (SEP −2.1), einsteinium (SEP −2.2), fermium (SEP −2.37), mendelevium (SEP −2.4), nobelium (SEP −2.5), lawrencium (SEP −2.0), or a combination thereof. In still further examples, the semiconductivity controller can include a transition metal. Suitable transition metals can include scandium (SEP −2.03), titanium (SEP −1.63), vanadium (SEP −1.13), chromium (SEP −0.9), manganese (SEP −1.18), yttrium (SEP −2.37), zirconium (SEP −1.55), niobium (SEP −1.1), hafnium (SEP −1.7), tantalum (SEP −0.81), or a combination thereof. In yet further examples, the semiconductivity controller can include a metalloid. Suitable metalloids can include boron (SEP −0.89), silicon (SEP −0.91), or a combination thereof. In some additional examples, the semiconductivity controller can include a post-transition metal. Suitable post-transition metals can include aluminum (SEP −1.68).

In some specific examples, the semiconductivity controller 106 can include lithium, sodium, potassium, rubidium, cesium, francium, beryllium, magnesium, calcium, strontium, barium, radium, lanthanum, cerium, praseodymium, neodymium, promethium, samarium, europium, gadolinium, terbium, dysprosium, holmium, erbium, thulium, ytterbium, lutetium, plutonium, americium, curium, berkelium, californium, einsteinium, fermium, mendelevium, nobelium, lawrencium, scandium, titanium, vanadium, chromium, manganese, yttrium, zirconium, niobium, hafnium, tantalum, boron, silicon, aluminum, or a combination thereof. In some specific examples, the semiconductivity controller can include one of lithium, sodium, potassium, rubidium, cesium, francium, beryllium, magnesium, calcium, strontium, barium, radium, lanthanum, cerium, praseodymium, neodymium, promethium, samarium, europium, gadolinium, terbium, dysprosium, holmium, erbium, thulium, ytterbium, lutetium, plutonium, americium, curium, berkelium, californium, einsteinium, fermium, mendelevium, nobelium, lawrencium, scandium, titanium, vanadium, chromium, manganese, yttrium, zirconium, niobium, hafnium, tantalum, boron, silicon, or aluminum. In some further examples, the semiconductivity controller can include two of lithium, sodium, potassium, rubidium, cesium, francium, beryllium, magnesium, calcium, strontium, barium, radium, lanthanum, cerium, praseodymium, neodymium, promethium, samarium, europium, gadolinium, terbium, dysprosium, holmium, erbium, thulium, ytterbium, lutetium, plutonium, americium, curium, berkelium, californium, einsteinium, fermium, mendelevium, nobelium, lawrencium, scandium, titanium, vanadium, chromium, manganese, yttrium, zirconium, niobium, hafnium, tantalum, boron, silicon, or aluminum.

The semiconductivity controller 106 can be present in the semiconductor material in a variety of amounts. Generally, the semiconductivity controller can be present in the semiconductor material in an amount from about 0.3 at % to about 18 at % based on the total number of atoms in the semiconductor material. In some additional examples, the semiconductivity controller can be present in the semiconductor material in an amount from about 0.5 at % to about 5 at %, from about 1 at % to about 8 at %, from about 5 at % to about 12 at %, or from about 8 at % to about 16 at % based on the total number of atoms in the semiconductor material.

As discussed previously, the semiconductor material used to form the semiconductor composite layer 101 and the amount of oxygen 108 in the semiconductor material can affect the semiconductive properties of the semiconductor material. For example, depending on the valencies or oxidation states of the carrier mobility contributor, the amorphous phase stabilizer, and the semiconductivity controller, various amounts of oxygen can be employed to achieve a suitable semiconductor material. Generally, the amount of oxygen present in the semiconductor material can approach an amount suitable to fill the valencies of the carrier mobility contributor, the amorphous phase stabilizer, and the semiconductivity controller. Generally, the amount of oxygen in the semiconductor material can be from about 45 at % to about 67 at % based on the total number of atoms in the semiconductor material. For example, where the carrier mobility contributor is cadmium, the amorphous phase stabilizer is zinc, and the semiconductivity controller is magnesium, the amount of oxygen can approach 50 at % (e.g. from about 45 at % to about 50 at %, for example). As another example, where the carrier mobility contributor is lead, the amorphous phase stabilizer is tin, and the semiconductivity controller is silicon, the amount of oxygen can approach 67 at % (e.g. from about 62 at % to about 67 at %, for example). In some specific examples, the amount of oxygen can be from about 45 at % to about 55 at %, from about 50 at % to about 60 at %, or from about 55 at % to about 65 at % based on the total number of atoms in the semiconductor material.

The carrier mobility contributor 102, the amorphous phase stabilizer 104, and the semiconductivity controller 106 can be present in the semiconductor material in a variety of atomic ratios. In some examples, the carrier mobility contributor and the amorphous phase stabilizer can be present in the semiconductor material at an atomic ratio of from about 1:2 to about 50:1 (carrier mobility contributor:amorphous phase stabilizer). In other examples, the carrier mobility contributor and the amorphous phase stabilizer can be present in the semiconductor material at an atomic ratio of from about 2:3 to about 40:1, from about 1:1 to about 30:1, from about 3:2 to about 20:1, or from about 2:1 to about 10:1 (carrier mobility contributor:amorphous phase stabilizer).

In some additional examples, the carrier mobility contributor 102 and the semiconductivity controller 106 can be present in the semiconductor material at an atomic ratio of from about 2:3 to about 150:1 (carrier mobility contributor:semiconductivity controller). In some additional examples, the carrier mobility contributor and the semiconductivity controller can be present in the semiconductor material at an atomic ratio of from about 1:1 to about 120:1, from about 3:2 to about 100:1, from about 2:1 to about 80:1, from about 3:1 to about 60:1, from about 4:1 to about 40:1, or from about 5:1 to about 20:1 (carrier mobility contributor:semiconductivity controller).

In yet additional examples, the amorphous phase stabilizer 104 and the semiconductivity controller 106 can be present in the semiconductor material at an atomic ratio of from about 1:30 to about 80:1 (amorphous phase stabilizer:semiconductivity controller). In still other examples, the amorphous phase stabilizer and the semiconductivity controller can be present in the semiconductor material at an atomic ratio of from about 1:25 to about 50:1, from about 1:20 to about 40:1, from about 1:15 to about 30:1, from about 1:10 to about 20:1, from about 1:5 to about 10:1, or from about 1:2 to about 2:1.

### Semiconductor Devices

The semiconductor composite layers described herein can be included in a variety of semiconductor devices. In some examples, the semiconductor devices can include a substrate, a gate electrode, a diametric material or gate insulator, a semiconductor, a source electrode, a drain electrode, and a semiconductivity controller.

The source electrode and the drain electrode can be formed from an intermediate layer that is composed of the carrier mobility contributor and the amorphous phase stabilizer as described above. For example, the intermediate layer may be placed over the gate insulator and the semiconductivity controller may be placed over a portion of the intermediate layer. The semiconductivity controller may then be fused into the portion of the intermediate layer. The portion of the intermediate layer that is fused with the semiconductivity controller will form a semiconductivity portion. The semiconductivity portion of the intermediate layer then separates two remaining portions of the intermediate layer that have not been fused with the semiconductivity controller. These two remaining portions may be the source electrode and the drain electrode that are separated by the semiconductivity portion.

The gate electrode can likewise include or be formed of a variety of materials. In some examples, the gate electrode can include or be formed of a metal, such as indium, tin, aluminum, titanium, copper, nickel, silver, molybdenum, tungsten, tantalum, the like, or a combination thereof. In some examples, the gate electrode can include or be formed of a transparent conductor material, such as indium tin oxide (ITO), Cd₂SnO₄, ZnSnO₃, Zn₂SnO₄, doped SnO₂, doped ZnO, doped In₂O₃, the like, or a combination thereof. In some examples, the gate electrode can include or be formed of the same material as the drain electrode, the source electrode, or both. In other examples, the gate electrode can be formed of or include different materials from the drain electrode, the source electrode, or both. The gate electrode can be formed using a variety of processes, such as spray pyrolysis, sputtering, CVD, pulsed laser deposition, PVD, ALD, or the like. The dimensions of the gate electrode are not particularly limited and can depend on the particular design and intended use of the semiconductor device. In some non-limiting examples, the gate electrode can have a thickness of from about 10 nm to about 1000 nm, or from about 50 nm to about 500 nm, or from about 20 nm to about 200 nm.

The gate dielectric or gate insulator can include or be formed of a variety of dielectric materials. Non-limiting examples can include silicon dioxide (SiO₂), silicon nitride (Si₃N₄), aluminum oxide (Al₂O₃), tantalum pentoxide (Ta₂O₅), hafnium(IV)oxide (HfO₂), Zirconium(IV)oxide (ZrO₂), strontium titanate (ST), barium strontium titanate (BST), lead zirconium titanate (PZT), strontium bismuth tantalate (SBT), bismuth zirconium titanate (BZT), magnesium oxide (MgO), polymeric dielectric materials (e.g. polyvinylidene difluoride (PVDF), polyimide, fluorinated polyimide, polyethylene, polystryrene, etc.), other organic dielectric materials, the like, or a combination thereof.

In some examples, the gate dielectric can include or be formed of a uniform or substantially uniform material. In other examples, the gate dielectric can be formed of a gradient material (e.g. having a changing concentration of a material constituent from one side to the other). In still other examples, the gate dielectric can include or be formed of layers of different materials. The gate dielectric can be formed using a variety of processes, such as PVD, CVD, ALD, evaporation, sputtering, pulsed laser deposition, spray pyrolysis, the like, or a combination thereof. The dimensions of the gate dielectric are not particularly limited and can depend on the particular design and intended use of the semiconductor device. In some non-limiting examples, the gate dielectric can have a thickness of from about 10 nm to about 1000 nm, from about 50 nm to about 500 nm, from about 20 nm to about 200 nm, about 30 nm to about 300 nm, or from about 40 nm to about 400 nm.

As described previously, the channel can be formed of a semiconductor material as described herein. The channel can be formed using a variety of techniques, such as spray pyrolysis, sputtering, CVD, pulsed laser deposition, PVD, ALD, or the like. The dimensions of the channel are also not particularly limited and can depend on the particular design and intended use of the semiconductor device. In some non-limiting examples, the channel can have a thickness of from about 10 nm to about 1000 nm, from about 50 nm to about 500 nm, from about 20 nm to about 200 nm, about 30 nm to about 300 nm, or from about 40 nm to about 400 nm.

The semiconductor devices can also include a substrate. A variety of suitable substrate materials can be employed in the semiconductor devices. Non-limiting examples can include silicon wafers, glass, quartz, metal foils, photoresist (e.g. SU-8), organic substrate materials (e.g. polydimethylsiloxane (PDMS), cyclic olefin copolymer (COC)), polymide (PI), or the like.

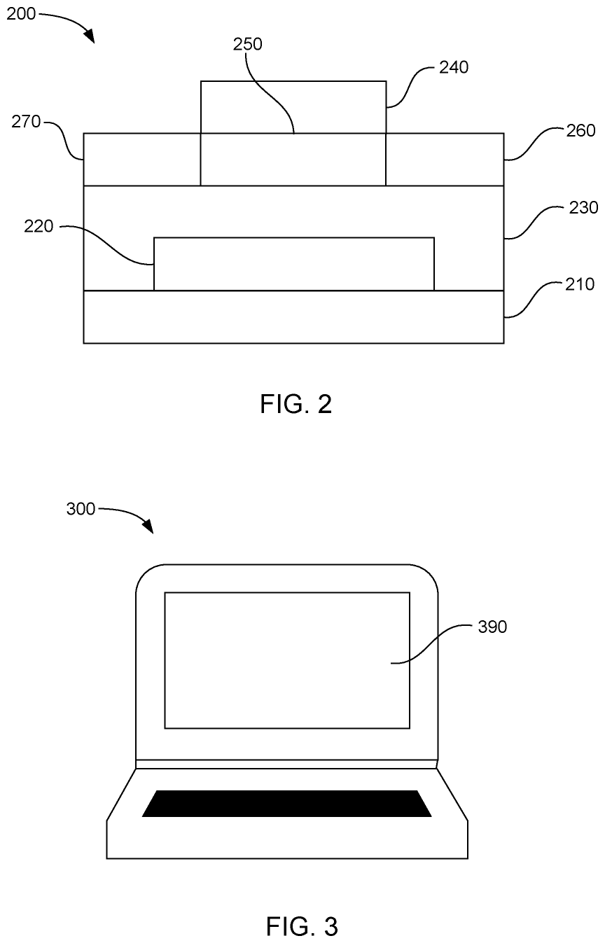

The semiconductor devices can be designed in a variety of ways. FIG. 2 illustrates a non-limiting example of a possible semiconductor device structure. For example, FIG. 2 illustrates a semiconductor device 200. In this particular example, a gate electrode 220 is formed on a substrate 210. A gate insulator 230 is positioned over the gate electrode 220 and the substrate 210. An intermediate layer is placed over the gate insulator 230. The intermediate layer can be composed of a carrier mobility contributor and an amorphous phase stabilizer. A semiconductivity controller 240 is placed over a portion of the intermediate layer. For example, semiconductor device 200 depicts semiconductivity controller 240 over a semiconductive portion 250. The semiconductive portion 250 can be fused with the semiconductivity controller material of the semiconductivity controller 240 such that semiconductive portion 250 is composed of carrier mobility contributor, amorphous phase stabilizer, a semiconductivity controller, and oxygen. The portions of the intermediate layer that are not fused with the semiconductivity controller 240 form a source electrode 270 and a drain electrode 260. The source electrode 270 and the drain electrode 260 are separated by the semiconductive portion 250.

Various other structures and design considerations can also be employed depending on the particular application of the semiconductor device. As such, the semiconductor device can be a transistor (e.g. a field-effect transistor, a thin-film transistor, etc.), or any other suitable semiconductor device and can be used for fabricating a chip, an integrated circuit, a microelectronic device, or the like.

### Electronic Devices

The present disclosure also describes electronic devices. The electronic devices can include a semiconductor device as described herein electrically integrated as part of the electronic device. Generally, the electronic device can include any electronic device employing an integrated circuit or transistor. Non-limiting examples can include a display, a display panel backplane, a printer, an ink-jet printer, an amplifier, a memory device, a global positioning system (GPS) device, a server, a modem, a router, a personal computer, a laptop computer, a calculator, a tablet, a phone, a speaker, a television, a media player, an electronic reader, a projector, a smart device, a remote control, the like, or a combination thereof.

As one non-limiting example, an electronic device 300 is illustrated in FIG. 3. The electronic device represents a laptop computer, which can include a variety of components individually including a semiconductor device as described herein. One example of a component (or individual electronic device) is a display 390. In further detail, the display can include pixel devices that can be coupled to semiconductor devices (e.g. thin-film transistors), such as those described herein. The display can include various control lines for supplying an addressable signal voltage to the semiconductor devices to influence the semiconductor devices to turn on and off to control the pixel devices to generate a visible image on the display. Various other components (or individual electronic devices) of the electronic device can also include semiconductor devices, as described herein, for performing a variety of functions.

### Methods for Manufacturing Semiconductors

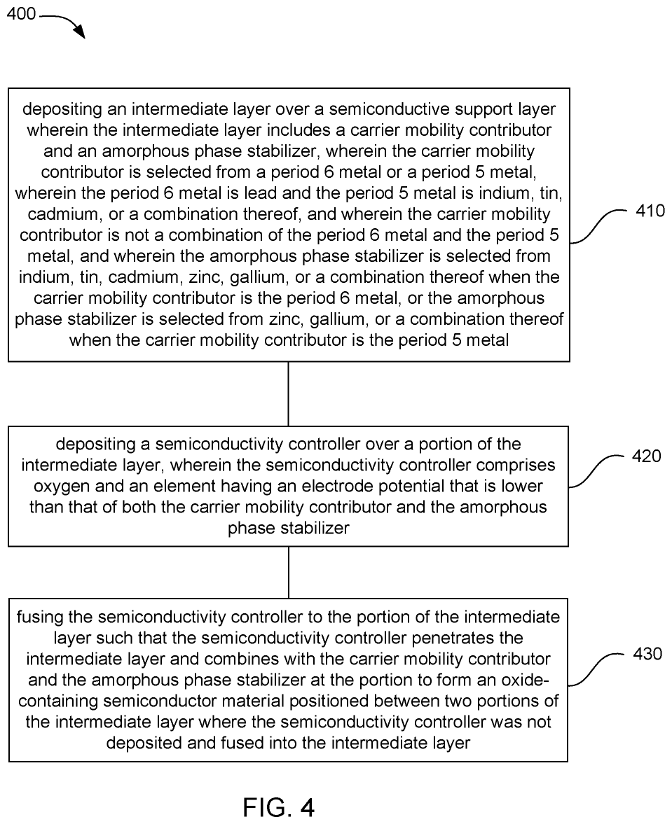

FIG. 4 is a flowchart illustrating an example method 400 of manufacturing a semiconductor composite layer. The method includes depositing 410 an intermediate layer over a semiconductive support layer wherein the intermediate layer includes a carrier mobility contributor and an amorphous phase stabilizer, wherein the carrier mobility contributor is selected from a period 6 metal or a period 5 metal, wherein the period 6 metal is lead and the period 5 metal is indium, tin, cadmium, or a combination thereof, and wherein the carrier mobility contributor is not a combination of the period 6 metal and the period 5 metal, and wherein the amorphous phase stabilizer is selected from indium, tin, cadmium, zinc, gallium, or a combination thereof when the carrier mobility contributor is the period 6 metal, or the amorphous phase stabilizer is selected from zinc, gallium, or a combination thereof when the carrier mobility contributor is the period 5 metal. The method further includes depositing 420 a semiconductivity controller over a portion of the intermediate layer, wherein the semiconductivity controller comprises oxygen and an element having an electrode potential that is lower than that of both the carrier mobility contributor and the amorphous phase stabilizer. The method further includes fusing 430 the semiconductivity controller to the portion of the intermediate layer such that the semiconductivity controller penetrates the intermediate layer and combines with the carrier mobility contributor and the amorphous phase stabilizer at the portion to form an oxide-containing semiconductor material positioned between two portions of the intermediate layer where the semiconductivity controller was not deposited and fused into the intermediate layer.

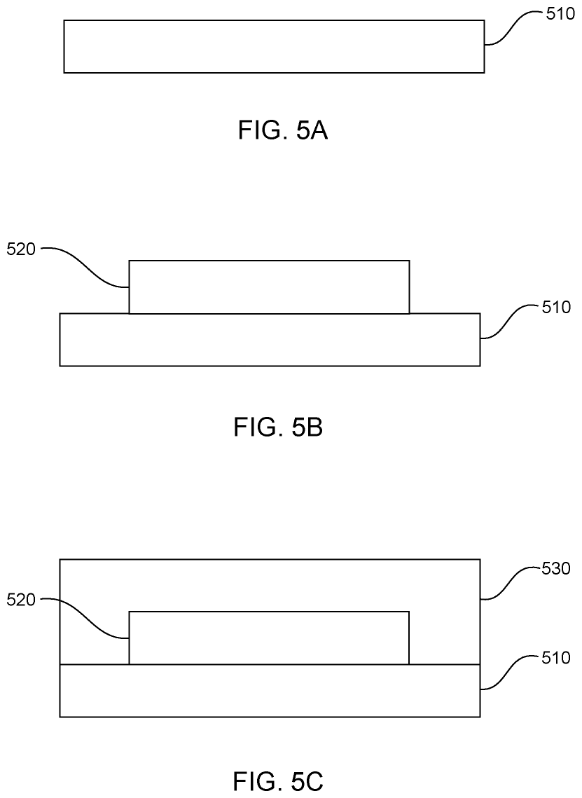

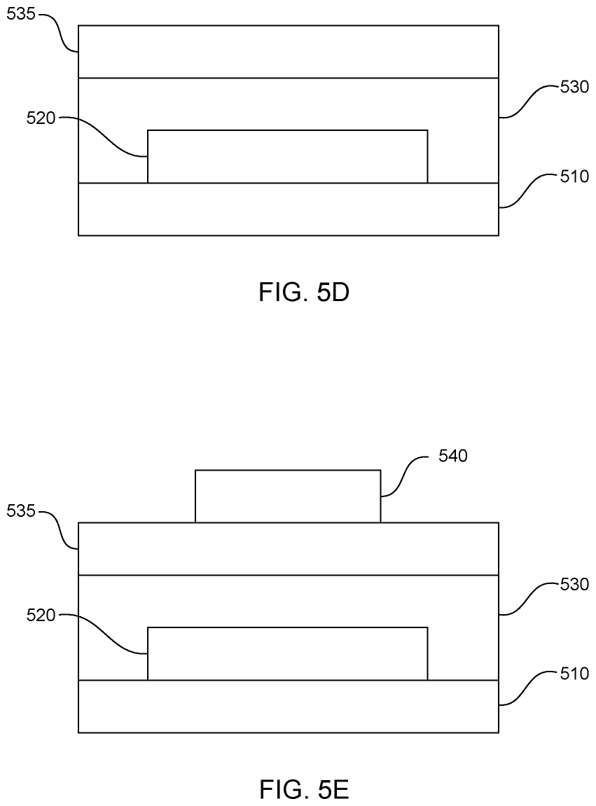

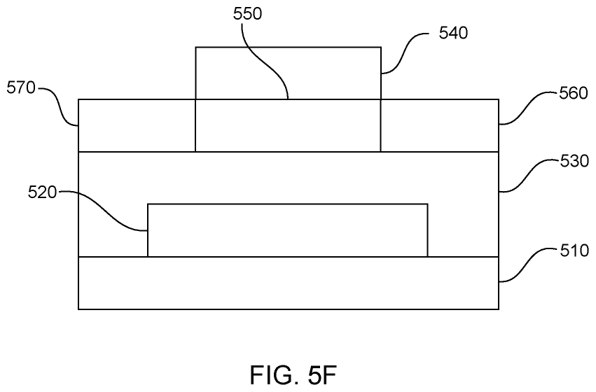

FIGS. 5A-5F show cross-sectional views illustrating another example method for manufacturing a semiconductor composite layer. In FIG. 5A, a substrate 510 is formed. In FIG. 5B, a gate electrode 520 can cover a portion of a surface of the substrate 510. In FIG. 5C, a gate insulator 530 can cover exposed surfaces of the gate electrode 520 and portions of the substrate 510. In FIG. 5D, an intermediate layer 535 can be deposited over the gate insulator 530. The intermediate layer 535 can be composed of a carrier mobility contributor and an amorphous phase stabilizer.

In FIG. 5E, a semiconductivity controller 540 can be deposited over a portion of the intermediate layer 535. In FIG. 5F, the semiconductivity controller 540 can be fused to the portion of the intermediate layer that is covered by the semiconductivity controller 540. The fusing can be accomplished using heating processes such as annealing. The fusing can fuse semiconductivity materials and oxygen into the portion of the intermediate layer covered by the semiconductivity controller 540. This fused portion of the intermediate layer can be referred to as a semiconductivity portion 550. The semiconductivity portion 550 can include the carrier mobility contributor, the amorphous phase stabilizer, the semiconductivity controller material, and oxygen fused together to form a semiconductor. The semiconductivity portion 550 separates two portions of the intermediate layer that are not fused with the semiconductivity controller 540. These two portions can be referred to as a source electrode 570 and a drain electrode 560 and can function as electrodes in a semiconductor device.

### Fusing

In one example, semiconductivity controller material is fused to a portion of an intermediate layer that can be composed of a carrier mobility contributor and an amorphous phase stabilizer as described above. It should be appreciated that the fusing can be accomplished using a variety of techniques. For example, the fusing can be accomplished by heating the semiconductivity controller material and the intermediate layer. In another example, annealing techniques may be employed. In metallurgy and materials science, annealing can be a heat treatment that alters the physical and sometimes chemical properties of a material to increase its ductility and reduce its hardness, making it more workable. Annealing involves heating a material above its recrystallization temperature, maintaining a suitable temperature for a suitable amount of time, and then cooling. Annealing may be accomplished in an oven that heats the semiconductivity controller and the intermediate layer to temperatures from about 200° C. to about 500° C., from about 200° C. to about 400° C., about 200° C. to about 300° C., from about 400° C. to about 500° C., or any other suitable temperatures.

In annealing, atoms may migrate in a crystal lattice and the number of dislocations decreases, leading to a change in ductility and hardness. As the material cools it recrystallizes. Thus the semiconductivity controller material and oxygen may form a pattern with the carrier mobility contributor and the amorphous phase stabilizer. The fusing may be accomplished using other techniques such as using microwaves.

### Definitions

It is noted that, as used in this specification and the appended claims, the singular forms “a,” “an,” and “the” include plural referents unless the content clearly dictates otherwise.

As used herein, the term “about” is used to provide flexibility to a numerical range endpoint by providing that a given value may be “a little above” or “a little below” the endpoint. The degree of flexibility of this term can be dictated by the particular variable and would be within the knowledge of those in the field technology to determine based on experience and the associated description herein.

As used herein, a plurality of items, structural elements, compositional elements, and/or materials may be presented in a common list for convenience. However, these lists should be construed as though individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include not just the numerical values explicitly recited as the limits of the range, but also all the individual numerical values or sub-ranges encompassed within that range as if individual numerical values and sub-ranges are explicitly recited. For example, an atomic ratio range of about 1 at % to about 20 at % should be interpreted to include not just the explicitly recited limits of about 1 at % and about 20 at %, but also to include individual atomic percentages such as 2 at %, 11 at %, 14 at %, and sub-ranges such as 10 at % to 20 at %, 5 at % to 15 at %, etc.

The terms, descriptions, and figures used herein are set forth by way of illustration and are not meant as limitations. Many variations are possible within the disclosure, which is intended to be defined by the following claims—and equivalents—in which all terms are meant in the broadest reasonable sense unless otherwise indicated.

What is claimed is:

1. A semiconductor composite layer, comprising:
a source electrode and a drain electrode individually comprising both a carrier mobility contributor and an amorphous phase stabilizer;
the carrier mobility contributor selected from a period 6 metal or a period 5 metal, wherein the period 6 metal is lead and the period 5 metal is indium, tin, cadmium, or a combination thereof, and wherein the carrier mobility contributor is not a combination of the period 6 metal and the period 5 metal;
the amorphous phase stabilizer selected from indium, tin, cadmium, zinc, gallium, or a combination thereof when the carrier mobility contributor is the period 6 metal, or the amorphous phase stabilizer is selected from zinc, gallium, or a combination thereof when the carrier mobility contributor is the period 5 metal; and
a semiconductive portion disposed between the source electrode and the drain electrode wherein the semiconductive portion comprises the carrier mobility contributor and the amorphous phase stabilizer, and further includes a semiconductivity controller not present in the source electrode and the drain electrode, the semiconductivity controller comprising oxygen and an element having an electrode potential that is lower than that of both the carrier mobility contributor and the amorphous phase stabilizer.

2. The semiconductor composite layer of claim 1, wherein the carrier mobility contributor and the amorphous phase stabilizer are present at the semiconductor composite layer at an atomic ratio of from 1:2 to 50:1.

3. The semiconductor composite layer of claim 1, wherein the carrier mobility contributor and the semiconductivity controller are present in the semiconductive portion at an atomic ratio of from 2:3 to 150:1.

4. The semiconductor composite layer of claim 1, wherein the element of the semiconductivity controller has an electrode potential from −0.8 to −3.1.

5. The semiconductor composite layer of claim 1, wherein the carrier mobility contributor is lead, and the amorphous phase stabilizer is selected from indium, tin, cadmium, zinc, gallium, or a combination thereof.

6. The semiconductor composite layer of claim 1, wherein the carrier mobility contributor is indium, tin, cadmium, or a combination thereof, and the amorphous phase stabilizer is zinc, gallium, or a combination thereof.

7. The semiconductor composite layer of claim 1, wherein the semiconductivity controller comprises of Al₂O₃, SiO₂, HfO₂, or Ta₂O₃.

8. A method of manufacturing a semiconductor composite layer, comprising:
depositing an intermediate layer over a semiconductive support layer wherein the intermediate layer includes a carrier mobility contributor and an amorphous phase stabilizer, wherein the carrier mobility contributor is selected from a period 6 metal or a period 5 metal, wherein the period 6 metal is lead and the period 5 metal is indium, tin, cadmium, or a combination thereof, and wherein the carrier mobility contributor is not a combination of the period 6 metal and the period 5 metal, and wherein the amorphous phase stabilizer is selected from indium, tin, cadmium, zinc, gallium, or a combination thereof when the carrier mobility contributor is the period 6 metal, or the amorphous phase stabilizer is selected from zinc, gallium, or a combination thereof when the carrier mobility contributor is the period 5 metal;
depositing a semiconductivity controller over a portion of the intermediate layer, wherein the semiconductivity controller comprises oxygen and an element having an electrode potential that is lower than that of both the carrier mobility contributor and the amorphous phase stabilizer; and
fusing the semiconductivity controller to the portion of the intermediate layer such that the semiconductivity controller penetrates the intermediate layer and combines with the carrier mobility contributor and the amorphous phase stabilizer at the portion to form an oxide-containing semiconductor material positioned between two portions of the intermediate layer where the semiconductivity controller was not deposited and fused into the intermediate layer.

9. The method of claim 8, wherein the two portions of the intermediate layer form a source electrode and a drain electrode, both of which include the carrier mobility contributor and the amorphous phase stabilizer, but not the semiconductivity controller.

10. The method of claim 8, wherein the semiconductive support layer is formed by depositing a gate electrode over a portion of a substrate and depositing a gate insulator material over exposed surfaces of the gate electrode and over the substrate, wherein the intermediate layer is deposited over a surface of the gate insulator material.

11. The method of claim 8, wherein the semiconductivity controller comprises of Al₂O₃, SiO₂, HfO₂, or Ta₂O₃.

12. The method of claim 8, wherein the fusing the semiconductivity controller to the portion of the intermediate layer is accomplished via an annealing process.

13. The method of claim 8, wherein the fusing the semiconductivity controller to the portion of the intermediate layer is accomplished by heating the semiconductivity controller and the intermediate layer to a temperature from about 200° C. to about 500° C.

14. An electronic device, comprising a semiconductor composite layer electrically integrated as part of the electronic device, the semiconductor composite layer, including:
a substrate;
a gate electrode deposited over a portion of the substrate;
a gate insulator material deposited over exposed surfaces of the gate electrode and the substrate;
a source electrode and a drain electrode individually comprising both a carrier mobility contributor and an amorphous phase stabilizer;
the carrier mobility contributor selected from a period 6 metal or a period 5 metal, wherein the period 6 metal is lead and the period 5 metal is indium, tin, cadmium, or a combination thereof, and wherein the carrier mobility contributor is not a combination of the period 6 metal and the period 5 metal;
the amorphous phase stabilizer selected from indium, tin, cadmium, zinc, gallium, or a combination thereof when the carrier mobility contributor is the period 6 metal, or the amorphous phase stabilizer is selected from zinc, gallium, or a combination thereof when the carrier mobility contributor is the period 5 metal; and
a semiconductive portion disposed between the source electrode and the drain electrode, wherein the semiconductive portion includes the carrier mobility contributor and the amorphous phase stabilizer, as well as a semiconductivity controller not present in the source electrode and the drain electrode, the semiconductivity controller comprising oxygen and an element having an electrode potential that is lower than that of both the carrier mobility contributor and the amorphous phase stabilizer.

15. The electronic device of claim 14, wherein the electronic device comprises a display, an amplifier, a memory device, a global positioning system (GPS) device, a server, a modem, a router, a personal computer, a laptop computer, a calculator, a tablet, a phone, a speaker, a television, a media player, a projector, a smart device, a remote control, or a combination thereof.
